(19) United States
(12) Patent Application Publication
(10) Pub. No.: US 2012/0196396 A1
(43) Pub. Date: Aug. 2, 2012

(54) METHOD FOR FABRICATING LIGHT EMITTING DIODE CHIP

(75) Inventors: Ming-Teng Kuo, Taoyuan County (TW); Chang-Ho Chen, Taoyuan County (TW)

(73) Assignee: WALSIN LIHWA CORP, Taoyuan County (TW)

(21) Appl. No.: 13/353,335

(22) Filed: Jan. 19, 2012

(30) Foreign Application Priority Data
Jan. 31, 2011 (TW) 100103741

(51) Int. Cl. H01L 33/62

(52) U.S. Cl. 438/42; 257/E33.062

(57) ABSTRACT

A method for fabricating a light emitting diode (LED) chip is provided. First, a substrate is provided. A buffer layer is formed on the substrate. The buffer layer is patterned to form a plurality of recesses on a surface thereof. A first type semiconductor layer is formed on the surface of the buffer layer. A portion of the surface where the first type semiconductor layer and the buffer layer are in contact constitutes a bonding surface, and voids exist between the buffer layer and the first type semiconductor layer. An active layer and a second type semiconductor layer are formed on the first type semiconductor layer in sequence. A second electrode is formed on the second type semiconductor layer. A lift-off process is performed to separate the first type semiconductor layer and the buffer layer.

### CROSS-REFERENCE TO RELATED APPLICATION

This application claims the priority benefit of Taiwan application serial no. 100103741, filed on Jan. 31, 2011. The entirety of the above-mentioned patent application is hereby incorporated by reference herein and made a part of this specification.

### BACKGROUND OF THE INVENTION

1. Field of the Invention

The invention relates to a method for fabricating a light emitting diode (LED) chip. More particularly, the invention relates to a method for fabricating an LED chip with relative small thickness by performing a lift-off process.

2. Description of Related Art

In recent years, luminescence efficiency of LEDs has been constantly improved. Consequently, fluorescent lamps and incandescent bulbs are gradually replaced with the LEDs in some fields, such as a scanner light source which requires fast response, a back or front light source of a liquid crystal display (LCD), automobile dashboard illumination, traffic signs, and general illumination devices. The LED converts electrical energy into light. When an electric current is applied to a semiconductor device with the aforesaid compounds, electrical energy is converted and released in the form of light through the combination of electrons and electron holes. In general, the LED is comprised of a substrate, an n-type doped semiconductor layer, an active layer, a p-type doped semiconductor layer, an n-type electrode, and a p-type electrode. In a horizontal-type LED structure, the n-type doped semiconductor layer is configured on the substrate, and the active layer is configured between the n-type doped semiconductor layer and the p-type doped semiconductor layer. The n-type electrode is configured on the p-type doped semiconductor layer, and the p-type electrode is configured on the n-type doped semiconductor layer.

In a conventional LED structure, the thickness of the LED is reduced by performing a grinding process for reducing the thickness of the substrate or by a laser lift-off process for separating the semiconductor layer and the substrate. However, the conventional grinding process may lead to contamination of and damages to the chip. Alternatively, in the conventional laser lift-off process for separating the semiconductor layer and the substrate, the yield rate may be unsatisfactory, or the time spent on the laser lift-off process is excessively long.

### SUMMARY OF THE INVENTION

The invention is directed to a method for fabricating an LED chip. In the fabricating method, a substrate is provided first. A buffer layer is formed on the substrate. The buffer layer is patterned to form a plurality of recesses on a surface thereof. A first type semiconductor layer is formed on the surface of the buffer layer. A portion of the surface where the first type semiconductor layer and the buffer layer are in contact constitutes a bonding surface, and voids exist between the buffer layer and the first type semiconductor layer. An active layer and a second type semiconductor layer are formed on the first type semiconductor layer in sequence. A second electrode is formed on the second type semiconductor layer.

The invention is further directed to a method for fabricating an LED chip. In the fabricating method, a substrate is provided first. A first buffer layer is formed on the substrate. The first buffer layer is patterned to form a plurality of recesses on a surface thereof. A second buffer layer is formed on the surface of the first buffer layer. Here, a portion of the surface where the second buffer layer and the first buffer layer are in contact constitutes a bonding surface, and voids exist between the first buffer layer and the second buffer layer. A first type semiconductor layer, an active layer, and a second type semiconductor layer are sequentially formed on the second buffer layer. A second electrode is formed on the second type semiconductor layer.

The invention is further directed to a method for fabricating an LED chip. In the fabricating method, a substrate is provided first. A buffer layer is formed on the substrate. A first type semiconductor layer is formed on the buffer layer. The first type semiconductor layer is patterned to form a plurality of recesses on a surface thereof. A second type semiconductor layer is formed on the surface of the first type semiconductor layer. Here, a portion of the surface where the second type semiconductor layer and the first type semiconductor layer are in contact constitutes a bonding surface, and voids exist between the first type semiconductor layer and the second type semiconductor layer. An active layer and a third type semiconductor layer are sequentially formed on the second type semiconductor layer. A second electrode is formed on the third type semiconductor layer.

In order to make the aforementioned and other features and advantages of the invention more comprehensible, embodiments accompanying figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1F are schematic views illustrating a process of fabricating an LED chip according to a first embodiment of the invention.

FIG. 2A and FIG. 2B are schematic views illustrating a process of fabricating an LED chip according to another embodiment of the invention.

FIG. 3A and FIG. 3B are schematic views illustrating a process of fabricating an LED chip according to another embodiment of the invention.

FIG. 4A to FIG. 4C are schematic views illustrating a process of fabricating an LED chip according to a second embodiment of the invention.

FIG. 5A and FIG. 5B are schematic views illustrating a process of fabricating an LED chip according to another embodiment of the invention.

FIG. 6A and FIG. 6B are schematic views illustrating a process of fabricating an LED chip according to another embodiment of the invention.

FIG. 7A to FIG. 7C are schematic views illustrating a process of fabricating an LED chip according to a third embodiment of the invention.

FIG. 8A and FIG. 8B are schematic views illustrating a process of fabricating an LED chip according to another embodiment of the invention.

FIG. 9A and FIG. 9B are schematic views illustrating a process of fabricating an LED chip according to another embodiment of the invention.

### DESCRIPTION OF EMBODIMENTS

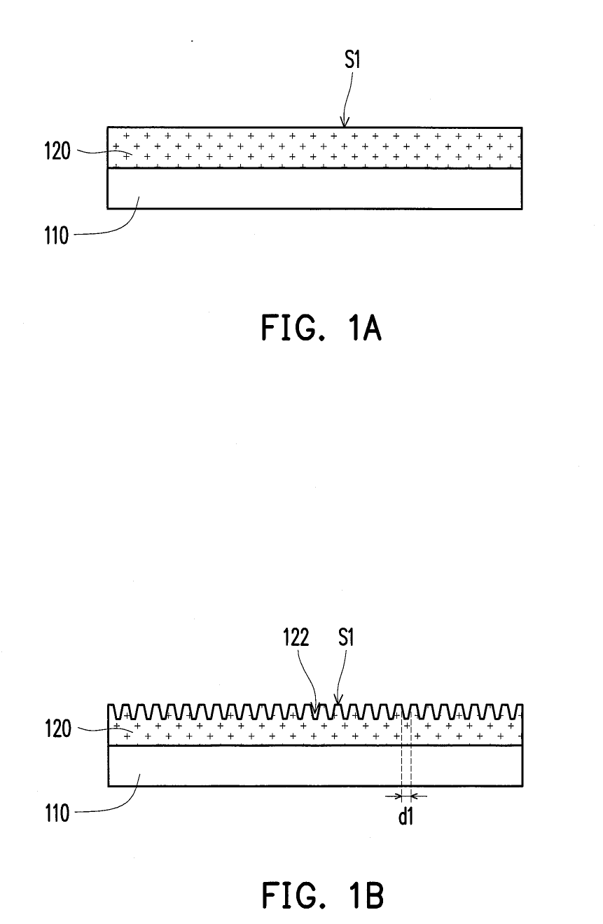

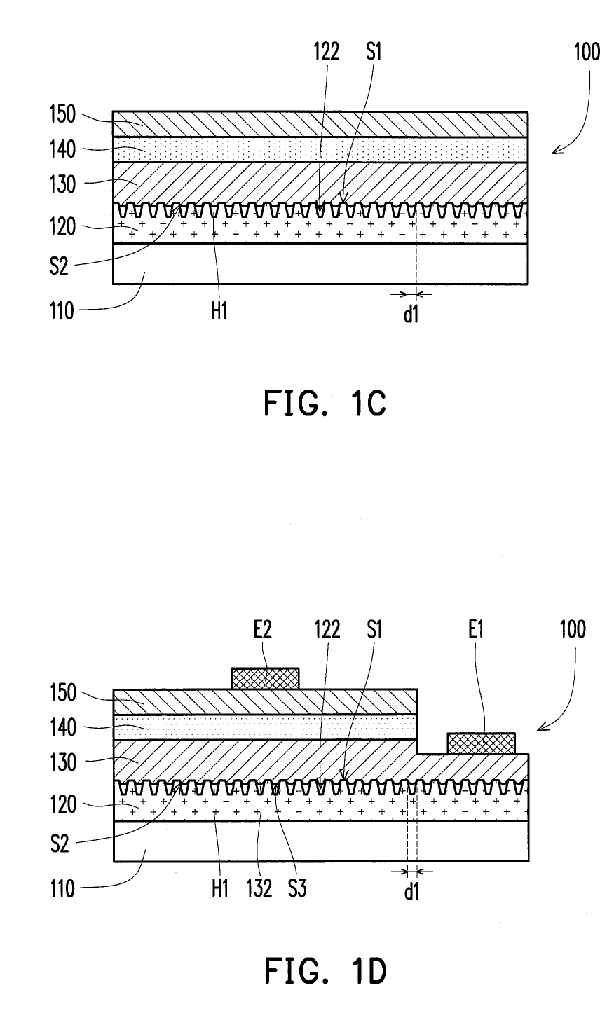

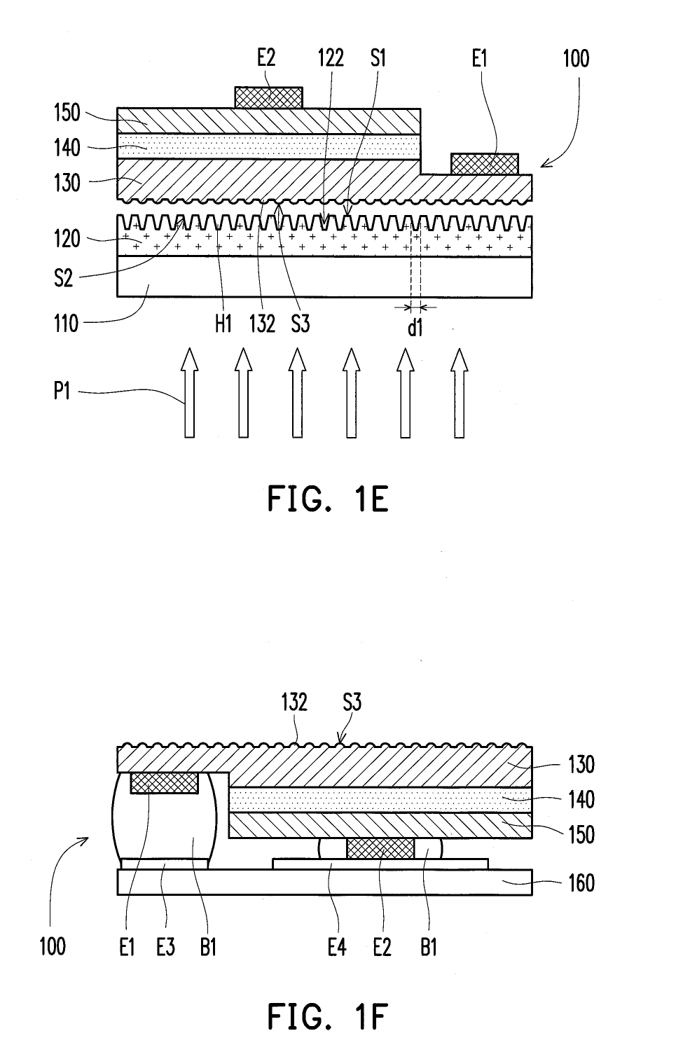

FIG. 1A to FIG. 1F are schematic views illustrating a process of fabricating an LED chip according to a first embodiment of the invention. With reference to FIG. 1A, a substrate 110 is provided, and a buffer layer 120 is formed on the substrate 110. In this embodiment, the substrate 110 can be a sapphire substrate, a silicon carbide (SiC) substrate, a zinc oxide (ZnO) substrate, an aluminum nitride substrate, a gallium nitride (GaN) substrate, a silicon (Si) substrate, a gallium phosphide (GaP) substrate, or a gallium arsenide (GaAs) substrate. In this embodiment, the substrate 110 is the sapphire substrate, for instance, which should not be construed as a limitation to the invention.

According to this embodiment, the buffer layer 120 can be formed on the substrate 110 by performing a metal organic chemical vapor deposition (MOCVD) process, a molecular beam epitaxial (MBE) process, or any other proper epitaxial growth process. In addition, the buffer layer 120 can be an un-doped or lightly-doped group III-V compound semiconductor layer. In this embodiment, the buffer layer 120 is the un-doped group III-V compound semiconductor layer, for instance, which should not be construed as a limitation to the invention. Besides, a material of the buffer layer 120 can be GaN, AlGaN, AlGaInN, AlInGaP, AlGaAs, InGaAs, or a combination thereof. More specifically, in this embodiment, the buffer layer 120 is made of the un-doped GaN, for instance, which should not be construed as a limitation to the invention.

The buffer layer 120 is patterned to form a plurality of recesses 122 on a surface S1 of the buffer 120, as shown in FIG. 1B. According to this embodiment, the buffer layer 120 can be patterned by performing a dry etching process, a wet etching process, or any other appropriate etching process. Here, the dry etching process is, for instance, a reactive ion etching (RIE) process, an inductively coupled plasma (ICP) etching process, or a high density plasma (HDP) etching process. By performing one of the aforesaid etching processes, the width d1 of each of the recesses 122 can be less than 5 μm and preferably less than 0.7 μm. Alternatively, the width d1 is less than 1 μm when an aspect ratio of each of the recesses 122 is greater than 2:1.

A first type semiconductor layer 130 is formed on the surface S1 of the buffer layer 120. A portion of the surface S1 where the first type semiconductor layer 130 and the buffer layer 120 are in contact constitutes a bonding surface S2, and voids H1 exist between the buffer layer 120 and the first type semiconductor layer 13, as indicated in FIG. 1C. Specifically, due to the small dimension of the recesses 122, when the first type semiconductor layer 130 is formed, the voids H1 are formed spontaneously between the first type semiconductor layer 130 and the buffer layer 120, and the voids H1 can be air voids or in any other type.

According to this embodiment, the first type semiconductor layer 130 can be formed on the buffer layer 120 by performing the MOCVD process, the MBE process, or any other proper epitaxial growth process. Additionally, the first type semiconductor layer 130 can be a heavily-doped group III-V compound semiconductor layer and can be made of GaN, AlGaN, AlGaInN, AlInGaP, AlGaAs, InGaAs, or a combination thereof In this embodiment, the first type semiconductor layer 130 is made of n-GaN, for instance, which should not be construed as a limitation to the invention.

An active layer 140 and a second type semiconductor layer 150 are sequentially formed on the first type semiconductor layer 130. In this embodiment, the active layer 140 and the second type semiconductor layer 150 can be formed by applying the method for forming the first type semiconductor layer 130 as described above. According to this embodiment, the second type semiconductor layer 150 can be a heavily-doped group III-V compound semiconductor layer and can be made of GaN, AlGaN, AlGaInN, AlInGaP, AlGaAs, InGaAs, or a combination thereof. In this embodiment, the second type semiconductor layer 150 is made of p-GaN, for instance, which should not be construed as a limitation to the invention. Besides, the active layer 140 can be a multiple quantum well (MQW).

The active layer 140 and the second type semiconductor layer 150 are patterned to expose a partial area of the first type semiconductor layer 130. A first electrode E1 and a second electrode E2 are respectively formed on the exposed area of the first type semiconductor layer 130 and the second type semiconductor layer 150, as indicated in FIG. 1D. According to this embodiment, the active layer 140, the second type semiconductor layer 150 and a portion of the first type semiconductor layer 130 can be patterned by performing the dry etching process, the wet etching process, or any other etching process as described above. Besides, the first electrode E1 and the second electrode E2 can be formed by way of MOCVD, electron beam, thermal evaporation, sputtering deposition, and so on.

A lift-off process P1 is performed to separate the first type semiconductor layer 130 and the buffer layer 120, as indicated in FIG. 1E. In the lift-off process P1 described in this embodiment, the bonding surface S2 is vaporized by implementing a laser lift-off process, for instance, so as to separate the first type semiconductor layer 130 and the buffer layer 120. Specifically, the recesses 122 or the voids H1 are still located on the surface S1 of the buffer layer 120. Therefore, the bonding surface S2 where the first type semiconductor layer 130 and the buffer layer 120 are in contact is discrete and occupies a relatively small area. In other words, the bonding surface S2 occupies a relatively small area that is smaller than the bottom surface of the buffer layer 120. As such, it is relatively easy to vaporize the bonding surface S2 by performing the laser lift-off process in order to separate the first type semiconductor layer 130 and the buffer layer 120.

Generally, when the thickness of the substrate 110 or the buffer layer 120 is reduced by performing a conventional grinding process, the LED chip can have a relatively small thickness, but the LED chip is likely to be contaminated or damaged when the substrate 110 or the buffer layer 120 is grinded. By contrast, according to this embodiment, the first type semiconductor layer 130 and the buffer layer 120 are separated by performing the aforesaid laser lift-off process, such that the issues arisen from the conventional grinding process can be prevented effectively. Moreover, since the recesses 122 are located on the surface S1 of the buffer layer 120, when the first type semiconductor layer 130 is formed on the buffer layer 120, the bonding surface S2 where the first type semiconductor layer 130 and the buffer layer 120 are in contact becomes discrete and has a relatively small area. Thereby, when the bonding surface S2 is vaporized by performing the laser lift-off process, the first type semiconductor layer 130 and the buffer layer 120 can be easily separated. That is to say, by applying the aforesaid fabricating method, the horizontal-type LED chip 100 with the relatively small thickness can be formed, and the horizontal-type LED chip 100 at least includes the first type semiconductor layer 130, the active layer 140, the second type semiconductor layer 150, the first electrode E1, and the second electrode E2.

Since a portion of the first type semiconductor layer 130 is formed in the recesses 122 of the buffer layer 120, a plurality of protrusions 132 extending outwardly are formed on a surface S3 of the first type semiconductor layer 130 when the first type semiconductor layer 130 and the buffer layer 120 are separated from each other. As such, when the horizontal-type LED chip 100 is driven, the light emission efficiency (i.e. external quantum efficiency) is rather favorable, as indicated in FIG. 1E.

In another embodiment of the invention, the horizontal-type LED chip 100 can also be transferred onto other substrates for other purposes. For instance, in the aforesaid method for fabricating the LED chip 100, the second type semiconductor layer 150 can be further bonded with a conductive substrate 160 which has a plurality of electrode pads E3 and E4. The electrode pads E3 and E4 are electrically connected to the first and second electrodes E1 and E2, respectively. Here, the electrical connection between the electrode pads E3 and E4 and the first and second electrodes E1 and E2 can be achieved by wires or bumps B1 (e.g., solder bumps, stud bumps), as indicated in FIG. 1F. In this embodiment, the electrode pads E3 and E4 are electrically connected to the first and second electrodes E1 and E2 by the bumps B1, which should not be construed as a limitation to the invention.

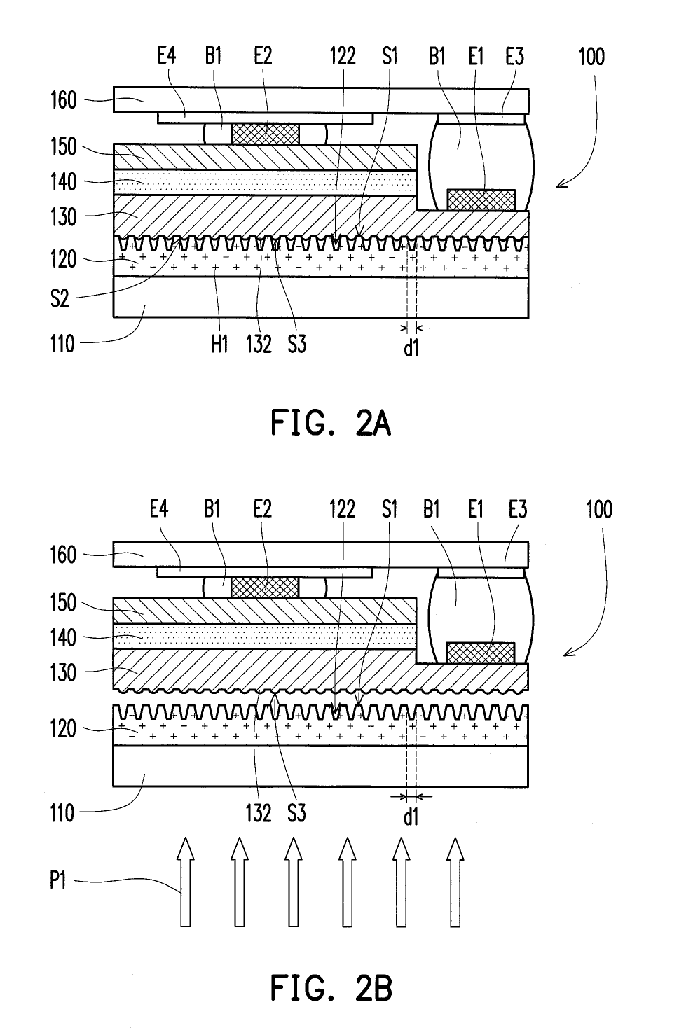

The two steps shown in FIG. 1E and FIG. 1F are interchangeable in another embodiment of the invention. Namely, after the step shown in FIG. 1D is performed, the manufacturing step shown in FIG. 2A and FIG. 2B can then be performed, such that the horizontal-type LED chip 100 can be formed in a different manner with reference to the above-mentioned method.

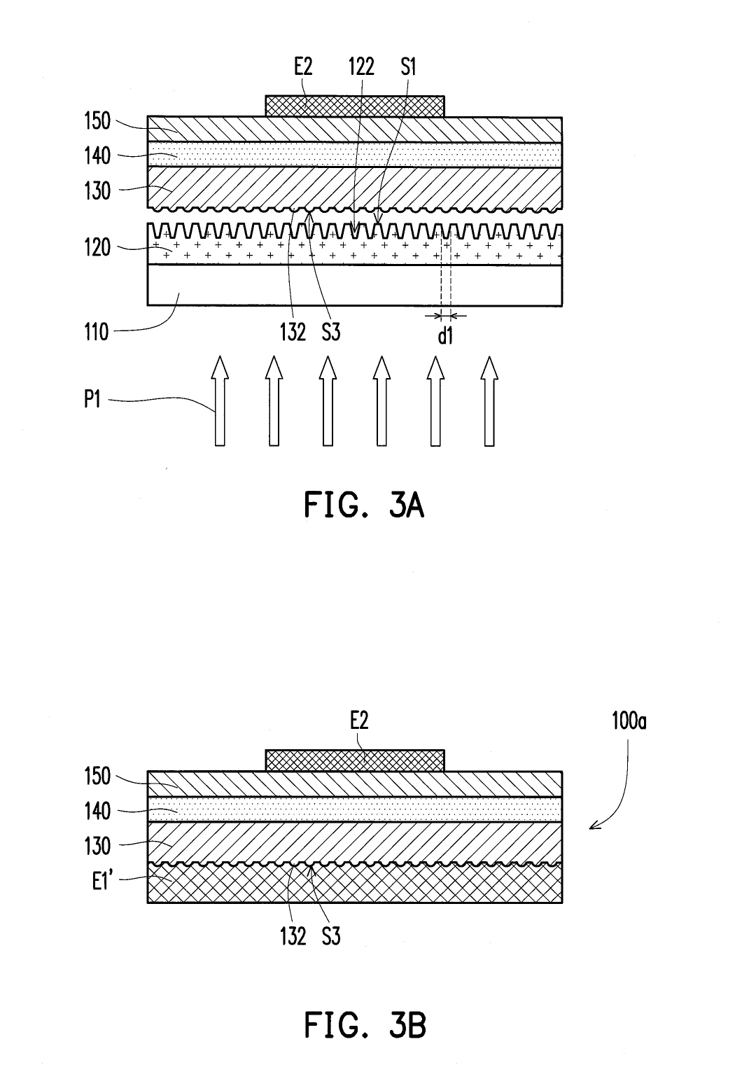

FIG. 3A and FIG. 3B are schematic views illustrating a process of fabricating an LED chip according to another embodiment of the invention. An LED chip 100a is formed by performing the steps shown in FIG. 1A to FIG. 1C. After the aforesaid second electrode E2 is formed on the second type semiconductor layer 150, the lift-off process P1 is performed, so as to separate the first type semiconductor layer 130 and the buffer layer 120, as indicated in FIG. 3A. After that, a first electrode E1′ (e.g., a conductive pad or a conductive substrate) is formed on the first type semiconductor layer 130, as indicated in FIG. 3B. So far, the vertical-type LED chip 100a can be formed.

The way to form the vertical-type LED chip 100a of this embodiment is similar to the way to form the horizontal-type LED chip 100, i.e., the first type semiconductor layer 130 and the buffer layer 120 are separated from each other, and the steps of fabricating the vertical-type LED chip 100a are as advantageous as the steps of fabricating the horizontal-type LED chip 100.

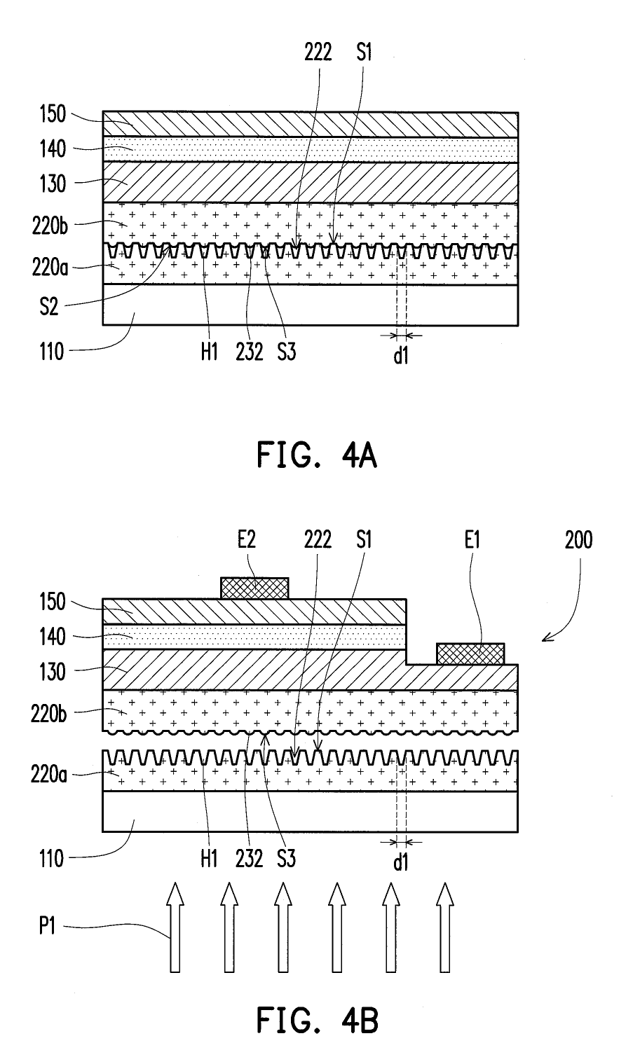

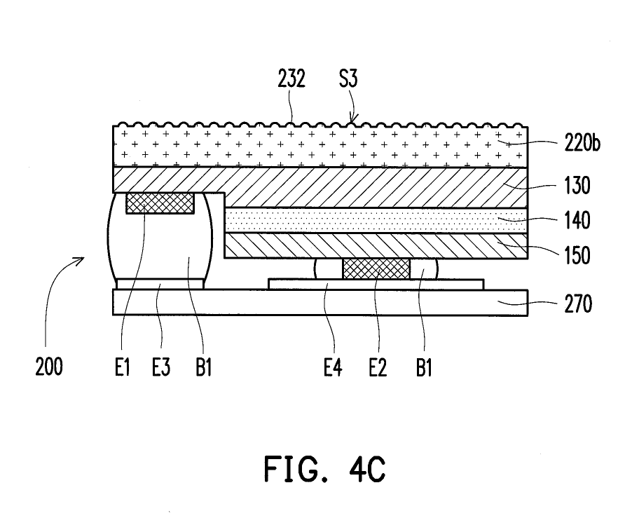

FIG. 4A to FIG. 4C are schematic views illustrating a process of fabricating an LED chip according to a second embodiment of the invention. The same reference numbers in FIG. 1A to FIG. 1F and in FIG. 4A to FIG. 4C denote the same components, and thus the materials and the fabricating steps of these components are not reiterated herein.

With reference to FIG. 4A, a first buffer layer 220a is formed on a substrate 110. Here, the first buffer layer 220a can be formed in the same manner as that of the buffer layer 120 (shown in FIG. 1A through FIG. 1F). Likewise, the first buffer layer 220a can be an un-doped or lightly-doped group III-V compound semiconductor layer. In this embodiment, the first buffer layer 220a is the un-doped group III-V compound semiconductor layer, for instance, which should not be construed as a limitation to the invention. Besides, the material of the first buffer layer 220 includes but is not limited to the above-mentioned material of the buffer layer 120 (shown in FIG. 1A through FIG. 1F). The first buffer layer 220a is patterned to form a plurality of recesses 222 on a surface S1 of the first buffer layer 220a. Here, the first buffer layer 220a can be patterned in the same manner as that of the buffer layer 120 (shown in FIG. 1A through FIG. 1F). Similarly, by performing one of the aforesaid etching processes, the width d1 of each of the recesses 222 can be less than 5 μm and preferably less than 0.7 μm. Alternatively, the width d1 is less than 1 μm when an aspect ratio of each of the recesses 222 reaches 2:1.

A second buffer layer 220b is formed on the surface S1 of the first buffer layer 220a. A portion of the surface S1 where the second buffer layer 220b and the first buffer layer 220a are in contact constitutes a bonding surface S2. Likewise, due to the width d1 of each of the recesses 222, when the second buffer layer 220b is formed, voids H1 are generated spontaneously between the second buffer layer 220b and the first buffer layer 220a, and the voids H1 can be air voids or in any other type. According to this embodiment, the second buffer layer 220b can be formed by performing the MOCVD process, the MBE process, or any other proper epitaxial growth process. The first type semiconductor layer 130, the active layer 140, and the second type semiconductor layer 150 are then sequentially formed on the second buffer layer 220b.

With reference to FIG. 4B, the active layer 140 and the second type semiconductor layer 150 are patterned to expose the first type semiconductor layer 130. A first electrode E1 and a second electrode E2 are then respectively formed on the exposed first type semiconductor layer 130 and the second type semiconductor layer 150. The aforesaid lift-off process P1 is performed to separate the first buffer layer 220a and the second buffer layer 220b.

Similarly, a portion of the second buffer layer 220b is formed in the recesses 222 of the first buffer layer 220a. Hence, when the first and second buffer layers 220a and 220b are separated from each other, a plurality of protrusions 232 extending outwardly are formed on a surface S3 of the second buffer layer 220b. Thereby, when the horizontal-type LED chip 200 is driven, favorable light emission efficiency (i.e. external quantum efficiency) can be achieved by the protrusions 232.

It is likely to transfer the horizontal-type LED chip 200 onto other substrates for other purposes according to the aforesaid method, as indicated in FIG. 4C.

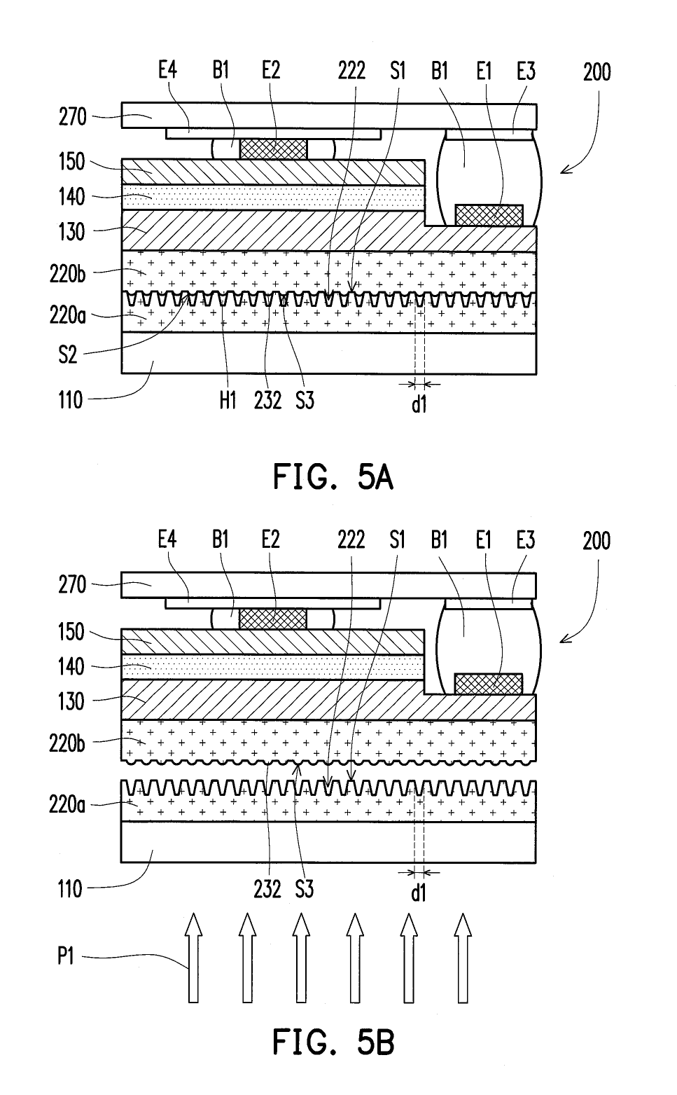

It can be observed from FIG. 4B to FIG. 4C that the horizontal-type LED chip 200 is formed by first separating the first and second buffer layers 220a and 220b and then transferring the LED chip 200 onto the conductive substrate 270. In an alternative embodiment, after the step shown in FIG. 4B is performed, the fabricating steps shown in FIG. 5A and FIG. 5B can then be performed, such that the LED chip 200 can be transferred to another substrate in a different manner.

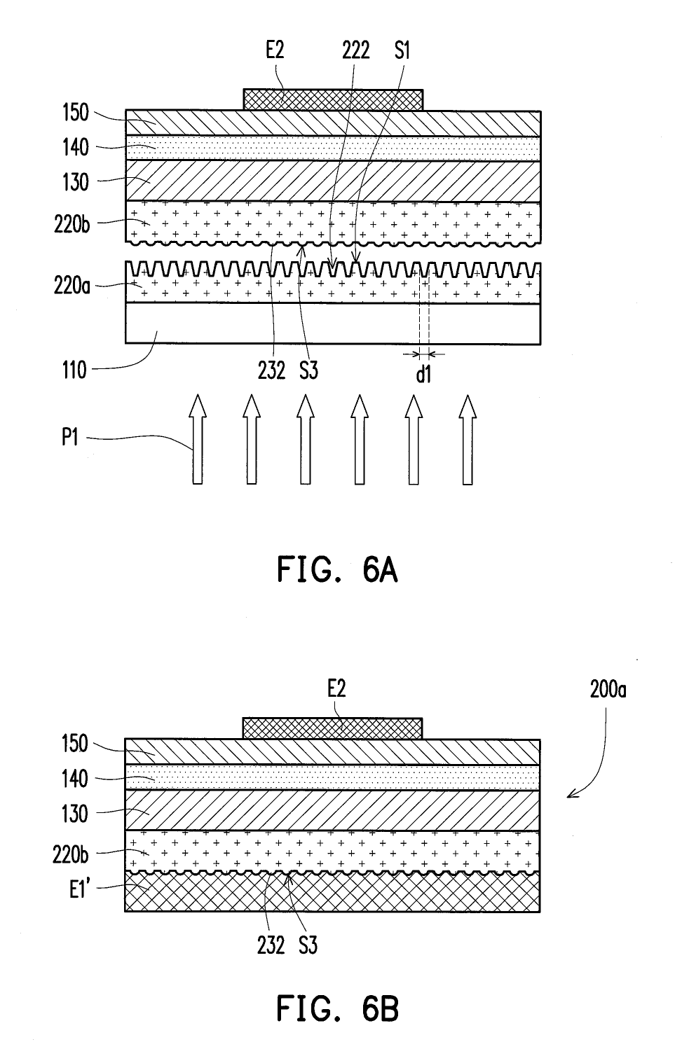

FIG. 6A and FIG. 6B are schematic views illustrating a process of fabricating an LED chip according to another embodiment of the invention. As shown in FIG. 6A, the difference between this embodiment and the previous embodiments lies in that the second electrode E2 is formed before the lift-off process P1 is performed, so as to separate the second buffer layer 220b and the first buffer layer 220a. With reference to FIG. 6B, a first electrode E1′ is formed below and bonded with the second buffer layer 220b. So far, the vertical-type LED chip 200a can be formed.

The way to form the vertical-type LED chip 200a of this embodiment is similar to the way to form the horizontal-type LED chip 200, i.e., the second buffer layer 220a and the first buffer layer 220a are separated from each other, and the steps of fabricating the vertical-type LED chip 200a are as advantageous as the steps of fabricating the horizontal-type LED chip 200.

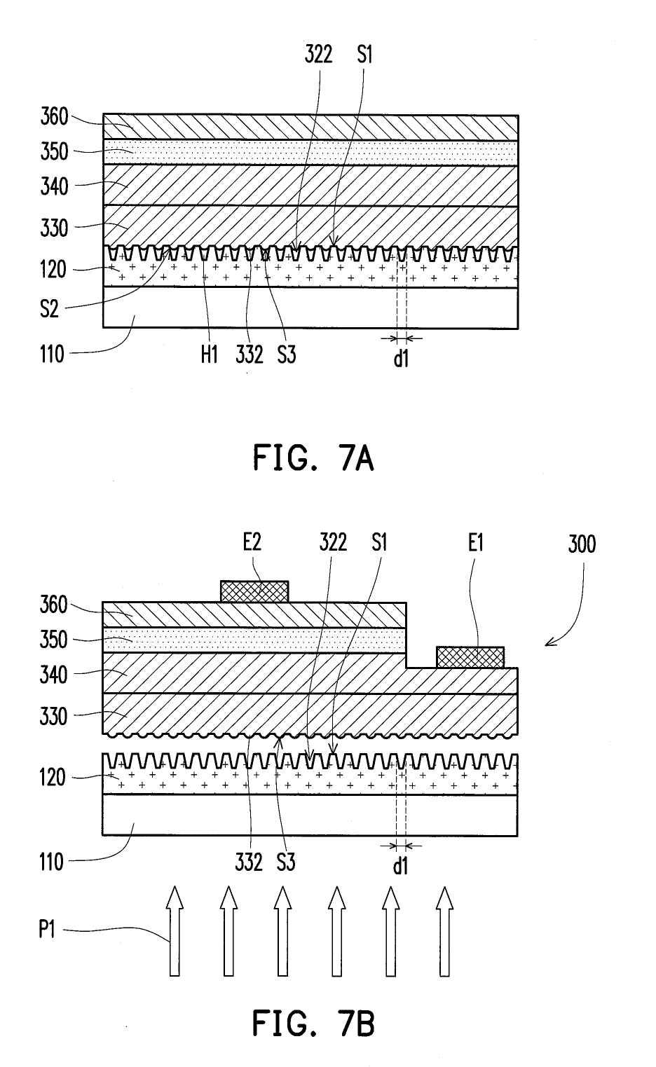

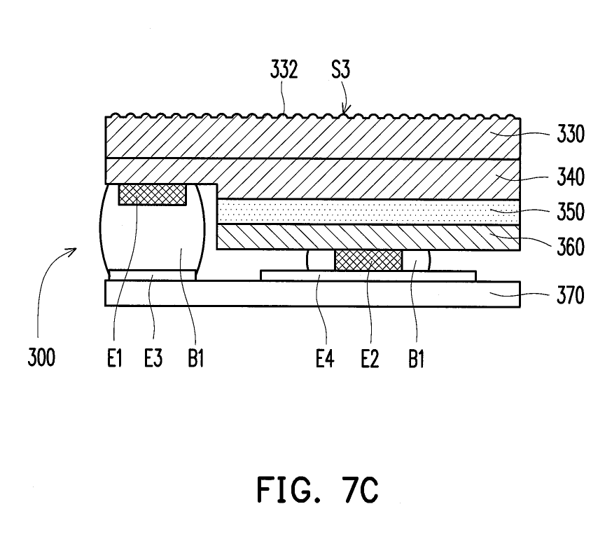

FIG. 7A to FIG. 7C are schematic views illustrating a process of fabricating an LED chip according to a third embodiment of the invention.

First, the buffer layer 120 is formed on the substrate 110 as described above, and the buffer layer 120 is patterned to form the recesses 322 on the surface S1, as shown in FIG. 7A. The materials, the fabricating steps, or the patterning method herein can refer to those described above and are not reiterated herein. Similarly, by performing one of the aforesaid etching processes, the width d1 of each of the recesses 322 can be less than 5 μm and preferably less than 0.7 μm. Alternatively, the width d1 is less than 1 μm when an aspect ratio of each of the recesses 322 reaches 2:1.

A first type semiconductor layer 330 is formed on the surface S1 of the buffer layer 120. A portion of the surface S1 where the first type semiconductor layer 330 and the buffer layer 120 are in contact constitutes a bonding surface S2, and voids H1 are spontaneously generated between the buffer layer 120 and the first type semiconductor layer 330. Specifically, due to the small dimension of the recesses 322, when the first type semiconductor layer 330 is formed, the voids H1 are spontaneously generated between the first type semiconductor layer 330 and the buffer layer 120, and the voids H1 can be air voids or in any other type. The material of the first type semiconductor layer 330 and the way to form the first type semiconductor layer 330 in this embodiment are similar to those of the first type semiconductor layer 130 as described above.

A second type semiconductor layer 340, an active layer 350, and a third type semiconductor layer 360 are sequentially formed on the first type semiconductor layer 330 in the same manner as that described in the previous embodiments. Besides, according to this embodiment, the second type semiconductor layer 340 and the second type semiconductor layer 360 can be heavily-doped group III-V compound semiconductor layers and can be made of GaN, AlGaN, AlGaInN, AlInGaP, AlGaAs, InGaAs, or a combination thereof. In this embodiment, the second type semiconductor layer 340 is made of n-GaN, for instance, and the third type semiconductor layer 360 is made of p-GaN, for instance. Besides, the active layer 350 can be an MQW.

The active layer 350 and the third type semiconductor layer 360 are patterned to expose the second type semiconductor layer 340, and the first electrode E1 and the second electrode E2 are respectively formed on the exposed second type semiconductor layer 340 and the third type semiconductor layer 360. The lift-off process P1 is then performed to separate the buffer layer 120 and the first type semiconductor layer 330, as indicated in FIG. 7B. The way to pattern the active layer 350 and the third type semiconductor layer 360 or the way to form the first and second electrodes E1 and E2 can refer to that described above.

Due to the voids H1, the bonding surface S2 where the buffer layer 120 and the first type semiconductor layer 330 are in contact is discrete and has a relatively small area. Therefore, it is rather easy to vaporize the bonding surface S2 by performing the laser process in order to separate the buffer layer 120 and the first type semiconductor layer 330. In other words, by applying the aforesaid method, the horizontal-type LED chip 300 with the relatively small thickness can be formed, and the horizontal-type LED chip 300 includes the first type semiconductor layer 330, the second type semiconductor layer 340, the active layer 350, the third type semiconductor layer 360, the first electrode El, and the second electrode E2.

Similarly, a portion of the first type semiconductor layer 330 is formed in the recesses 322 of the buffer layer 120, and therefore a plurality of protrusions 332 extending outwardly are formed on a surface S3 of the first type semiconductor layer 330 when the buffer layer 120 and the first type semiconductor layer 330 are separated from each other. As such, when the horizontal-type LED chip 300 is driven, favorable light emission efficiency (i.e. external quantum efficiency) can be achieved by the protrusions 332.

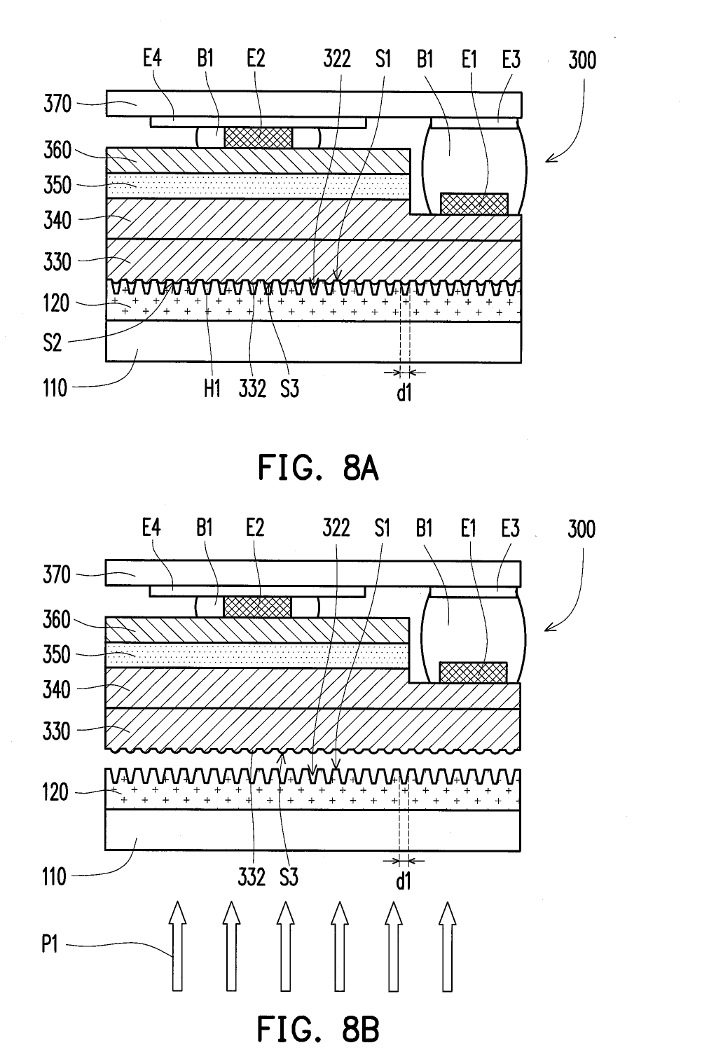

In addition, the LED chip 300 can also be transferred onto other substrates by applying the aforesaid method, as indicated in FIG. 7C. Alternatively, the fabricating steps shown in FIG. 8A and FIG. 8B can be performed, such that the horizontal-type LED chip 300 can be transferred onto another substrate in a different manner with reference to the above-mentioned method.

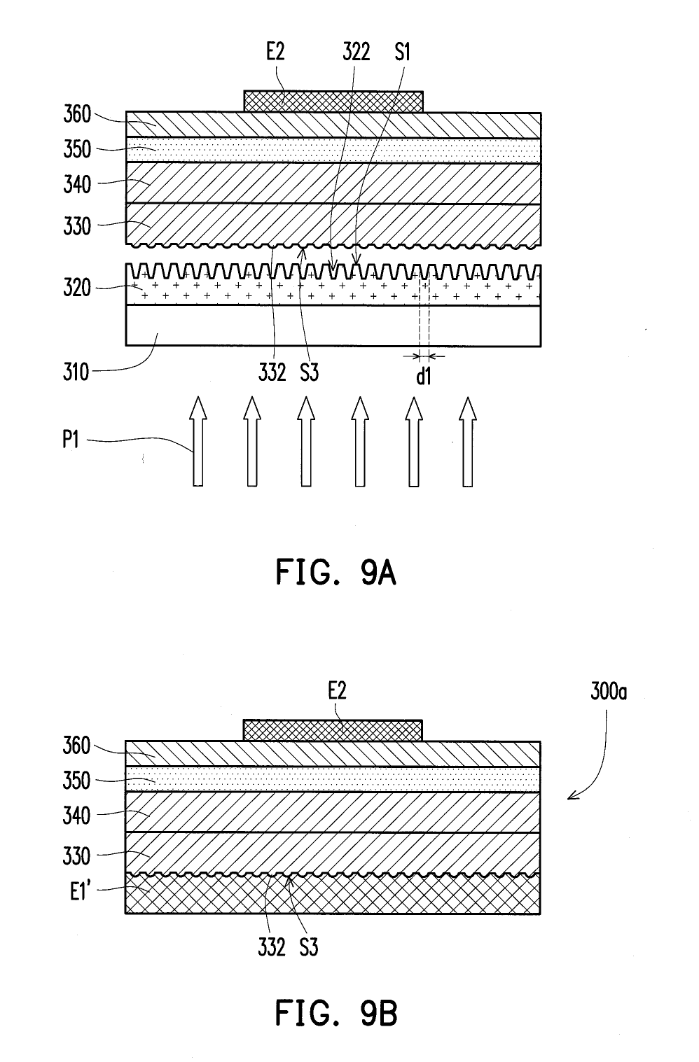

FIG. 9A and FIG. 9B are schematic views illustrating a process of fabricating an LED chip according to another embodiment of the invention. First, an LED chip 300a is formed, and the second electrode E2 is formed on the third type semiconductor layer 360. The lift-off process P1 is performed to separate the first type semiconductor layer 330 and the buffer layer 120, and the first electrode E1′ is formed below and bonded with the first type semiconductor layer 330. So far, the vertical-type LED chip 300a can be formed. The way to separate the first type semiconductor layer 330 and the buffer layer 120 in the vertical-type LED chip 300a of this embodiment is similar to and is as advantageous as that of the horizontal-type LED chip 300.

In light of the foregoing, the recesses are located on the surface of the buffer layer according to the invention. Hence, when a film layer (e.g., another buffer layer or the first type semiconductor layer) is formed on the buffer layer, the bonding surface where the film layer and the buffer layer are in contact becomes discrete and has a relatively small area. Thereby, when the bonding surface is vaporized by performing the laser lift-off process, the film layer and the buffer layer can be easily separated from each other, and the LED chip structure with a relatively small thickness can be further formed. Moreover, since a portion of the film layer on the buffer layer is formed in the recesses of the buffer layer, a plurality of protrusions extending outwardly are formed on the surface of the film layer when the film layer and the buffer layer are separated from each other. As such, when the LED chip is driven, the light emission efficiency can be improved by the protrusions.

The embodiments described hereinbefore are chosen and described in order to best explain the principles of the invention and its best mode practical application. It is not intended to be exhaustive to limit the invention to the precise form or to the exemplary embodiments disclosed. Namely, persons skilled in the art are enabled to understand the invention through various embodiments with various modifications as are suited to the particular use or implementation contemplated. It is intended that the scope of the invention be defined by the claims appended hereto and their equivalents in which all terms are meant in their broadest reasonable sense unless otherwise indicated. Any of the embodiments or any of the claims of the invention does not need to achieve all of the advantages or features disclosed by the invention.

Moreover, the abstract and the headings are merely used to aid in searches of patent files and are not intended to limit the scope of the claims of the invention.

What is claimed is:

1. A method for fabricating a light emitting diode chip, the method comprising:
providing a substrate;
forming a buffer layer on the substrate;
patterning the buffer layer to form a plurality of recesses on a surface thereof;
forming a first type semiconductor layer on the surface of the buffer layer, a portion of the surface where the first type semiconductor layer and the buffer layer are in contact constituting a bonding surface, voids existing between the buffer layer and the first type semiconductor layer; and
sequentially forming an active layer and a second type semiconductor layer on the first type semiconductor layer.

2. The method as claimed in claim 1, further comprising:
performing a lift-off process to separate the first type semiconductor layer and the buffer layer.

3. The method as claimed in claim 2, further comprising:
patterning the active layer and the second type semiconductor layer to expose the first type semiconductor layer;
forming a first electrode and a second electrode on the exposed first type semiconductor layer and the second type semiconductor layer respectively; and
covering the second type semiconductor layer with a conductive substrate having a plurality of electrode pads, the electrode pads being electrically connected to the first electrode and the second electrode respectively, wherein after the first type semiconductor layer and the buffer layer are separated, the first type semiconductor layer, the active layer, and the second type semiconductor layer are transferred to the conductive substrate.

4. The method as claimed in claim 1, wherein the first type semiconductor layer, the active layer, and the second type semiconductor layer are conformally formed on the buffer layer in sequence.

5. The method as claimed in claim 2, wherein the step of performing the lift-off process to separate the first type semiconductor layer and the buffer layer further comprises:
vaporizing the bonding surface to separate the first type semiconductor layer and the buffer layer.

6. The method as claimed in claim 5, wherein the step of vaporizing the bonding surface comprises performing a laser lift-off process.

7. The method as claimed in claim 1, wherein a width of each of the recesses is less than 5 μm, or less than 1 μm when an aspect ratio of each of the recesses is 2:1.

8. A method for fabricating a light emitting diode chip, the method comprising:
providing a substrate;
forming a first buffer layer on the substrate;
patterning the first buffer layer to form a plurality of recesses on a surface thereof;
forming a second buffer layer on the surface of the first buffer layer, a portion of the surface where the second buffer layer and the first buffer layer are in contact constituting a bonding surface, voids existing between the first buffer layer and the second buffer layer; and
sequentially forming a first type semiconductor layer, an active layer, and a second type semiconductor layer on the second buffer layer.

9. The method as claimed in claim 8, further comprising:
performing a lift-off process to separate the first buffer layer and the second buffer layer.

10. The method as claimed in claim 9, further comprising:
patterning the active layer and the second type semiconductor layer to expose the first type semiconductor layer;
forming a first electrode and a second electrode on the exposed first type semiconductor layer and the second type semiconductor layer respectively; and
covering the second type semiconductor layer with a conductive substrate having a plurality of electrode pads, the electrode pads being electrically connected to the first electrode and the second electrode respectively, wherein after the first buffer layer and the second buffer layer are separated, the first type semiconductor layer, the active layer, and the second type semiconductor layer are transferred to the conductive substrate.

11. The method as claimed in claim 9, wherein the step of performing the lift-off process to separate the first buffer layer and the second buffer layer further comprises:
vaporizing the bonding surface to separate the first buffer layer and the second buffer layer.

12. The method as claimed in claim 11, wherein the step of vaporizing the bonding surface comprises performing a laser lift-off process.

13. The method as claimed in claim 8, wherein the second buffer layer, the first type semiconductor layer, the active layer, and the second type semiconductor layer are conformally formed on the first buffer layer in sequence.

14. The method as claimed in claim 8, wherein a width of each of the recesses is less than 5 μm, or less than 1 μm when an aspect ratio of each of the recesses is 2:1.

15. A method for fabricating a light emitting diode chip, the method comprising:
providing a substrate;
forming a buffer layer on the substrate;
forming a first type semiconductor layer on the buffer layer;
patterning the first type semiconductor layer to form a plurality of recesses on a surface thereof;
forming a second type semiconductor layer on the surface of the first type semiconductor layer, a portion of the surface where the second type semiconductor layer and the first type semiconductor layer are in contact constituting a bonding surface, voids existing between the first type semiconductor layer and the second type semiconductor layer; and
sequentially forming an active layer and a third type semiconductor layer on the second type semiconductor layer.

16. The method as claimed in claim 15, further comprising:
performing a lift-off process to separate the first type semiconductor layer and the second type semiconductor layer.

17. The method as claimed in claim 16, further comprising:
patterning the active layer and the third type semiconductor layer to expose the second type semiconductor layer;
forming a first electrode and a second electrode on the exposed second type semiconductor layer and the third type semiconductor layer, respectively; and
covering the third type semiconductor layer with a conductive substrate having a plurality of electrode pads, the electrode pads being electrically connected to the first electrode and the second electrode respectively, wherein after the second type semiconductor layer and the first type semiconductor layer are separated, the second type semiconductor layer, the active layer, and the third type semiconductor layer are transferred to the conductive substrate.

18. The method as claimed in claim 16, wherein the step of performing the lift-off process to separate the first type semiconductor layer and the second type semiconductor layer further comprises:
vaporizing the bonding surface to separate the first type semiconductor layer and the second type semiconductor layer.

19. The method as claimed in claim 18, wherein the step of vaporizing the bonding surface comprises performing a laser lift-off process.

20. The method as claimed in claim 15, wherein a width of each of the recesses is less than 5 μm, or less than 1 μm when an aspect ratio of each of the recesses is 2:1.
